(19) United States
(12) Patent Application Publication
(10) Pub. No.: US 2025/0079204 A1
(43) Pub. Date: Mar. 6, 2025

(54) DIE TRANSFER METHOD AND APPARATUS

(71) Applicant: Silicon Box, Ltd., Singapore (SG)

(72) Inventors: Byung Joon Han, Singapore (SG); Byung Hoon Ahn, Singapore (SG)

(21) Appl. No.: 18/819,973

(22) Filed: Aug. 29, 2024

Related U.S. Application Data
(60) Provisional application No. 63/535,540, filed on Aug. 30, 2023.

(51) Int. Cl. H01L 21/67; H01L 21/683; H01L 21/78

(52) U.S. Cl. CPC H01L 21/67132; H01L 21/6836; H01L 21/78

(57) ABSTRACT

A system for holding multiple semiconductor die during a single placement operation onto a substrate. The system includes a stretchable mounting film having an adhesive to which two or more semiconductor die and a frame attaches. The frame has an open center portion formed by two or more outer support rail sections that are expandable to an expanded position. An optional frame lock may secure the frame in the expanded position. The frame may have four sections allowing expansion along two axis. The frame sections may have connection points configured to releasably attach the frame to a position control device that expands the sections to the expanded position. The frame and mounting tape can be expanded by stretching along a first axis, a second axis, or both, which separates the two or more dies adhesively attached to the mounting film while the dies are attached to the mounting film.

### 1. FIELD OF THE INVENTION

The innovation relates to wafer processing and in particular to a method and apparatus for processing wafers into dies and placement of multiple dies at a time.

### 2. RELATED ART

As is known in the art, a semiconductor package is a metal, plastic, glass, or ceramic casing containing one or more semiconductor devices or integrated circuits. The component that contains the operational integrated circuits are referred to as dies.

The die is a small, thin, piece of semiconducting material on which a functional circuit is fabricated. Typically, integrated circuits are produced in large batches on a single wafer of silicon or other type of semiconductor material through processes such as photolithography. The dies are originally formed as semiconductor wafers before being cut or sawn into individual dies. The number of dies that can be cut from the wafer depends on the size of the die and wafer, but it is not uncommon for over 10,000 die to be cut from a single wafer. In addition, many package products are mass produced, such that billions of packaged integrated circuits are made and sold yearly.

The die are ground, placed on a supporting substrate, and eventually into a package. The package provides a means for connecting the circuits on the dies to the external environment, such as printed circuit board, via leads such as lands, balls, or pins. The package also protects the internal integrated circuits.

One drawback of the prior art is the time-consuming process of picking up the dies and placing the dies onto a supporting surface, such as a substrate or package layer. When manufacturing a large number of packaged integrated circuits, the time required to align a pick-up tool with the die, then pick up and move the die to the desired location with the tool and then precisely align and place the die on the support surface, is significant, particularly when multiplied over billions of units, which is the estimated number of semiconductor units shipped worldwide over the course of a year.

FIG. 1 illustrates a generalized diagram of a prior art method for die placement onto a supporting surface. This is but one method, and other methods with associated systems are possible, although all prior art systems suffer from the described drawbacks. In FIG. 1, a wafer 104 is shown as having been sawn into numerous dies. A first arm is individually aligned above each die prior to picking up the die. This process may be referred to as a pick and place operation. Alignment is very important because die placement must occur to within 5 microns.

Then, the first arm 112, holding the die 108, flips 180 degrees from a first position 118 to a second position 120. The die 108 is then bottom side up. A second arm 128 then picks up the die 108 from an end of the first arm 112 and rotates from a first position 130 to a second position 132. At the second position, the second arm then aligns the die onto the supporting surface, such as a substrate 150. The die is secured to the substrate 150 as shown.

Due to the nature of the pick-up, alignment, arm rotations, placement alignment, the number of dies on a wafer, and vast number of dies manufactured per year, this is a time-consuming process, which undesirably limits production rates and reduces profit margins. While numerous die placement machines could be purchased to increase throughput, this adds additional cost and maintenance burdens on the manufacturer.

### SUMMARY

To overcome the drawbacks of the prior art and provide additional benefits, disclosed is a system for placing multiple semiconductor die during a single placement operation comprising a stretchable mounting tape having a first side and a second side. The first side has an adhesive thereon and the adhesive is configured to releasably adhere to two or more semiconductor die. A frame having an open center portion and a first frame portion and second frame portion forming an outer perimeter such that the first frame portion and the second frame portion may comprise one or more elements. The frame comprises a first frame portion and a second frame portion separated by a first gap and an opposing second gap. The first frame portion and the second frame portion both have a first frame side and a second frame side such that the first frame side is configured to adhesively bond, attach, or adhere to the adhesive on the mounting tape. Also part of this embodiment is one or more connection points on the first frame portion, the second frame portion or both. The one or more connection points are configured to releasably attach the frame to a frame position control device which determines a length of the first gap and the second gap, which separate the first frame portion and the second frame portion.

In one configuration, the first frame portion comprises a first section and a second section which are separated by a third gap, and the second frame portion comprises a third section and a fourth section which are separated by a forth gap. Further, in this configuration the first section and the second section have one or more connection points configured to releasably attach to the frame position control device, and third section and the second section have one or more connection points configured to releasably attach to the frame position control device. The open center portion may be circular. This embodiment may further comprise a pusher configured to push on the mounting tape to increase a distance between the two or more die. It is contemplated that the frame and the mounting tape can be expanded by applying force along a first axis, a second axis, or both to expand the length of the gaps. The two or more dies may comprise an entire wafer of dies. Once expanded, a distance between the two or more dies is increased, thereby allowing the entire wafer of dies to be placed during a single placement operation.

Also disclosed is a method for placing multiple semiconductor die during a single placement operation. This method includes providing a mounting film having adhesive on at least one side and an expandable frame and adhesively attaching the mounting film to the expandable frame when the expandable frame is in an unexpanded position. Then, attaching two or more connected semiconductor die to the adhesive on the mounting film and cutting the two or more semiconductor die to detach the two or more die from each other to create two or more cut die. This method also attaches the expandable frame to a frame expansion device, and with the frame expansion device, expanding the expandable frame from the unexpanded position to an expanded position. This increases a distance between the two or more cut die to create two or more cut expanded die. Then, during a single placement operation, attaching, to a substrate, the two or more cut expanded die on the mounting film.

In one embodiment, this method further comprises locking the frame in place with one or more frame locks to maintain the frame and the two or more cut expanded die in the expanded position. The step of attaching the two or more die to the substrate comprises an electrical connection between the two or more die and the substrate. This method may further comprise applying energy in the form of heat, irradiation, or light energy to the mounting film, and then removing the mounting film from the two or more die, such that the applying energy reduces the adhesive adhesion of the mounting film to the two or more die. In one configuration, expanding the expandable frame from the unexpanded position to the expanded position comprises pushing on the mounting film with a pusher pad. In addition, the step of expanding the expandable frame may comprise expanding the expandable frame and the two or more dies attached to the mounting film along a first axis and along a second axis, where the first axis is perpendicular to and in the same plane as the second axis. A side of the two or more die that is not attached to the mounting film is attached to the substrate.

Also disclosed is a system for holding and placing multiple semiconductor die during a single placement operation. In one exemplary configuration, the system includes stretchable mounting film having a first side and a second side. The first side has an adhesive thereon such that the adhesive is configured to releasably adhere to two or more semiconductor die. A frame is provided that has an open center formed by outer support rails, the outer support rails divided into two or more sections each having a first side and a second side, one of which is configured to attach to the mounting film. The two or more sections are expandable from an unexpanded position to an expanded position. A frame lock is configured to interact with a frame lock interface on the frame to secure the frame in the expanded position, the unexpanded position, or both.

In one configuration the two or more sections comprise four sections and the frame is expandable along two axis, and an amount of expansion along different axis may be different. The two or more sections may have one or more connection points configured to releasably attach the frame to a position control device, such that the position control device expands the two or more sections from the unexpanded position to the expanded position. The open center may be circular having a diameter of 100 mm to 450 mm to accept an entire wafer of dies on the mounting film.

The system may further comprise a pusher configured to expand the two or more sections, two or more semiconductor die, or both from the unexpanded position to the expanded position, and the mounting film attached to the frame. The frame may include one or more clamps to attach to the mounting film. In one configuration, the two or more dies comprise an entire wafer of cut dies and the frame, mounting film, and the entire wafer of cut dies are configured for movement and processing as a single element, including placement of an entire wafer of cut dies thereby allowing the entire wafer of cut dies to be placed during a single placement operation.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is a diagram illustrating a simplified die placement mechanism.

FIG. 2A illustrates a wafer mounted to a mounting film and wafer frame when the frame is in the unexpanded position.

FIG. 2B illustrates the wafer mounted to a wafer frame when the frame is in the expanded position.

FIG. 2C illustrates an exemplary frame position control device.

FIG. 3 illustrates a cut away side plan view of an alternative system for expanding the dies.

FIG. 4A, FIG. 4B, FIG. 4C, and FIG. 4D illustrate the dies and mounting film as processed during a large-scale die transfer process onto a substrate or other surface.

FIG. 5 illustrates one exemplary embodiment of a single die to substrate electrical connection.

### DETAILED DESCRIPTION

To overcome the drawbacks of the prior art and provide additional benefits, a die transfer method and apparatus is disclosed that allows for transfer of multiple die during a single transfer operation. In general, a wafer of dies is mounted on stretchable mounting film, which is connected to an expandable frame when the frame (and mounting film) is in the collapsed (stretched) position. The wafer is then subject to sawing to separate each die from other dies, while still attached to the stretchable mounting film. Then, the frame is extended to an expanded position, which in turn stretches the mounting film, causing the dies to expand outward with mounting film. This separates the dies to positions, relative to the other dies of the wafer, suitable of placement on a substrate during a single transfer operation. This method and associated exemplary apparatus is described below.

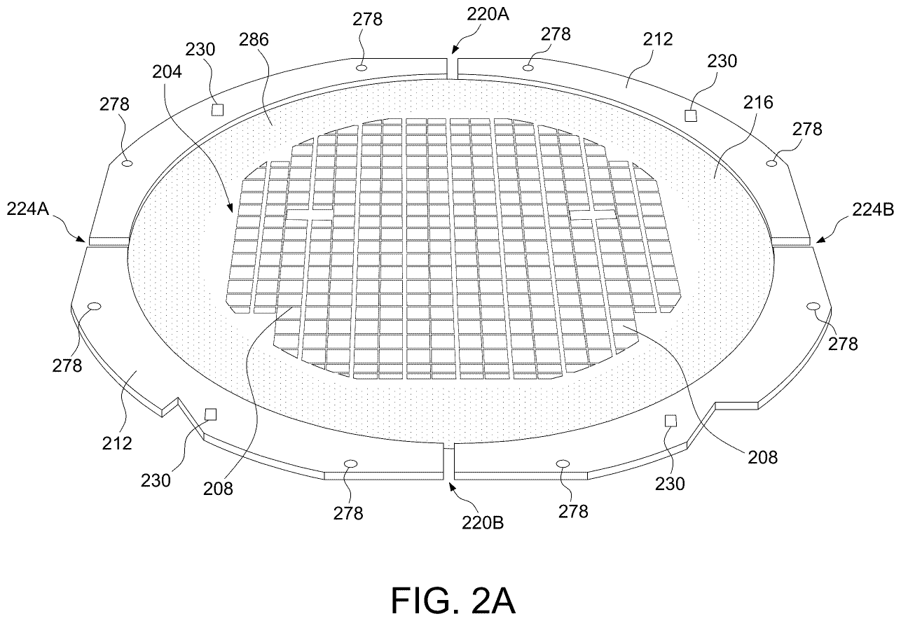

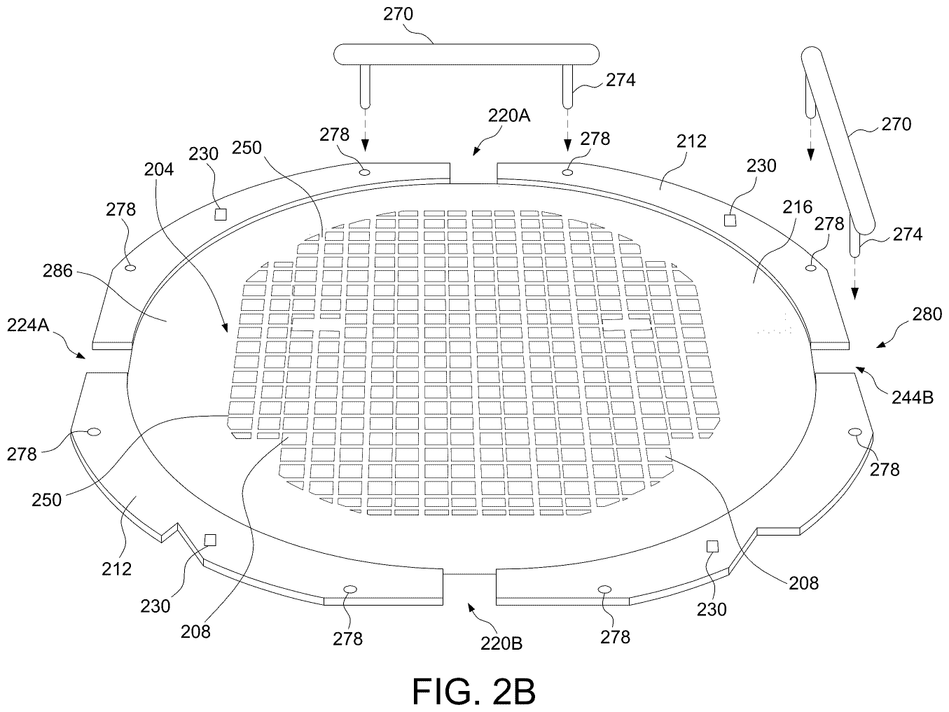

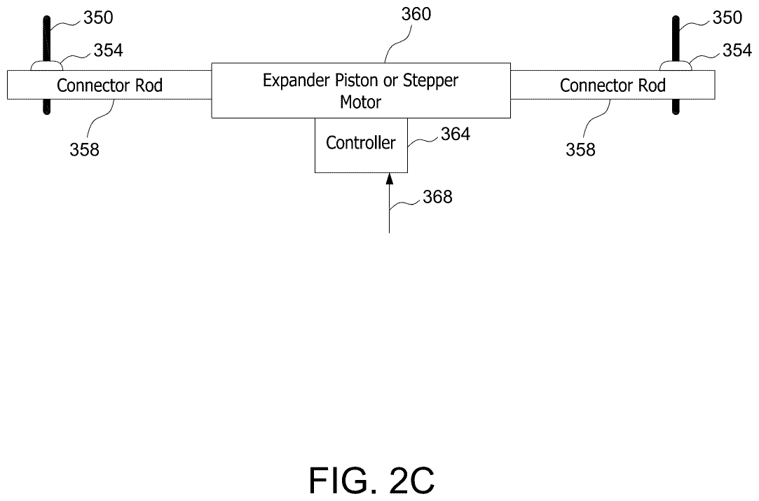

FIG. 2A illustrates a wafer mounted to a mounting film and wafer frame when the frame is in an unexpanded position. This is but one possible arrangement which may be utilized to secure the die during sawing and then expand the dies as disclosed herein. In this example embodiment, a wafer 204 is provided and is adhesively attached to mounting film 216. The mounting film 216 may be referred to as mounting tape. The mounting film 216 may be a large sheet of expandable material with adhesive 286 on at least one side such that the wafer is adhered to the mounting tape. Other attachment means are contemplated other than, or in addition to, adhesive attachment. The wafer 204 is composed of numerous dies 208 as is understood in the art.

The mounting film 216 is also adhesively or otherwise attached to an expandable frame 212. The frame has vertical expansion gaps 224A, 224B and horizontal expansion gaps 220A, 220B which allow the frame 212 to be expanded vertically and horizontally, also referred to as expanded in two dimensions or two axis. As shown in FIG. 2A, the expandable frame is shown in the unexpanded position such that the expansion gaps 220A, 220B, 224A, 224B are narrow. As such the die is attached to the mounting tape and the dies have not yet been sawn apart during semiconductor processing. In one embodiment, connection points or 230 shown as holes, are provided in the frame to apply force to the frame so as to pull the frame outward during a frame expansion process. In other embodiments, other arrangements or structure may be used to pull the frame apart other than the connections points 230 configured as holes. A rod, shaft, pin, hook or any type linkage of a frame position control device may interact with the interface points 230 to impart the force from the frame position control device to the interface 230 to cause the frame 212 to move, such as to expand to separate the die 208.

When the wafer 204 is secured to the expanding frame 212 in the unexpanded state shown in FIG. 2A, the wafer is in an unsawn state such that all the dies are still connected. Prior to expansion of the expanding frame 212, the wafer 204 is sawn to separate the wafer into individual dies 208. The wafer may be cut into individual dies using any method known in the art or developed in the future, such as but not limited to laser cutting or physical cutting using a rotating or vibrating saw. After sawing or cutting, each die 208 is still adhesively or otherwise attached to the mounting film 216.

FIG. 2B illustrates the wafer mounted to a wafer frame when the frame is in the expanded position. As compared to FIG. 2A, identical or similar elements are identified with identical reference numbers. The wafer is sawn into individual dies 208 to separate the dies from other dies. The die 208 are still attached to the mounting film 216. In one embodiment, the frame 212 can be a frame that consists of 4 pieces. Therefore, it can be expanded along with tape by vertical and horizontal force. In addition, the frame 212 can be one piece that allows for expansion in only the vertical and horizontal direction by vertical and horizontal force.

The force is applied to the frame 212, such as in the vertical and the horizontal direction, to thereby expand the frame at the expansion gaps 220A, 220B, 224A, 224B, which in turn stretches the mounting frame and the mounting film 216, which is attached to the frame. As shown in FIG. 2B, stretching the mounting film 216 forces the dies 208, which are attached to the mounting film, to also separate thereby forming gaps 250 between the dies. Thus, the die are pulled apart from each other while still attached to the mounting film 216.

The mounting film 216 is configured to be ridged and taut to thereby support the dies in position, but also stretchable under sufficient lateral force, such as along an x axis and a y axis to expand which creates gaps 250 or expands the saw lines gaps between the die. The gaps 250 are expanded in the horizontal and the vertical direction as shown in FIG. 2B. It is contemplated that the horizontal gap distance may differ from the vertical gap distance or be the same. Any amount of gap distance between the dies may be created to suitably align the dies 208 with the substrates to which the dies will eventually be placed upon. The mounting tape 216 may remain in the stretched (expanded) state even after the force is removed from the frame 212, or may maintain its residual forces and seek to return to an unstretched state once pressure is released from the frame. As such, the frame 212 may include one or more frame locks 270 which fix the frame into the expanded position by interacting with a frame lock interface 278. The frame lock 270 includes shafts which extend into the frame lock interface 278, which may be holes or other openings. Multiple frame locks 270 may be utilized to fully secure the frame 212.

The mounting tape and mounting film is available from Nitto, SK (Nitto.com) located in Japan and Korea. Mounting tape is similar to mounting film and these terms may be used interchangeably. Mounting tape may be narrower in size than mounting film, which may be larger to attach to an entire wafer of dies.

FIG. 2C illustrates an exemplary frame position control device. This is but one possible structure for expanding or contracting the frame. Expanding the frame, when the frame and the dies are attached to the mounting film/tape will increase the distance between each die. As shown in this example embodiment, the frame position control device includes pins 350 which engage the frame 212, such as the holes or interface 278 in the frame. Near the bottom of the pins 350 are support collars 354, which support the frame 212.

Attached to each pin 350 is a connector rod 358 that extends from the pin 350 to an expander piston or stepper motor 360. The expander piston or stepper motor 360 may be any type device that is configured to impart precise movement to the frame 212. The expander piston or stepper motor 360 receives input from a controller 364 to accurately control movement of the frame 212. The controller 364 may comprise any type electrical or electronic device configured to provide a control signal to the expander piston or stepper motor 360. The controller 364 may include an interface to receive instructions from a user or remote device. The controller 364 may comprise a processor configured to execute machine executable code, an ASIC, DSP, dedicated logic or any other related device.

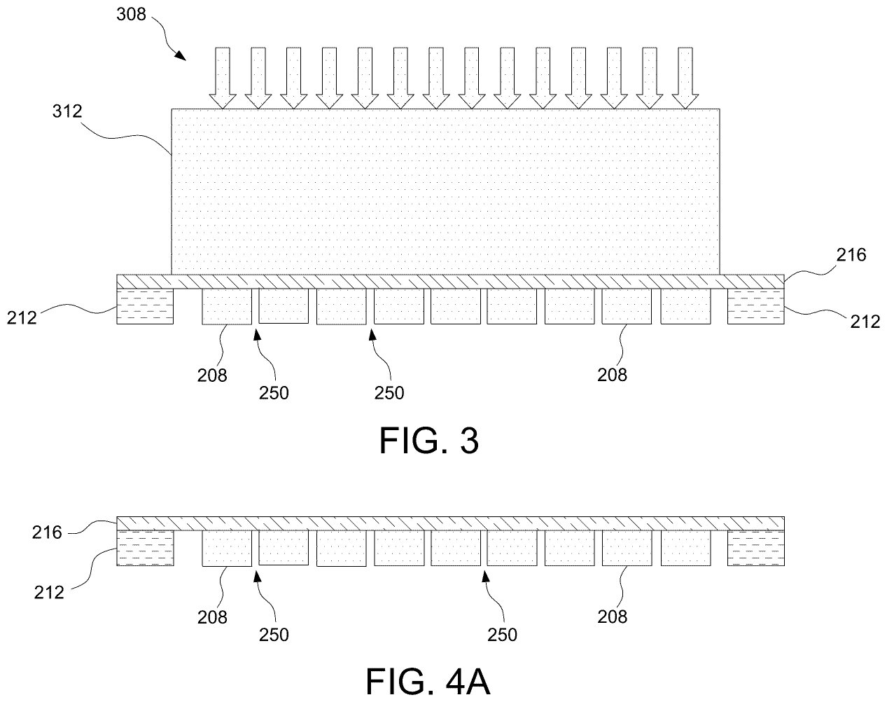

FIG. 3 illustrates a cut away side plan view of an alternative system for expanding the dies. This is but one possible configuration and others will, upon reading this disclosure, arrive at similar systems for expanding the dies which are covered by this disclosure. In this embodiment, the die 208 are similarly attached to the mounting film 216, such as with an adhesive connection. The mounting film 216 is also adhesively attached to the frame 212, as discussed above. Also as discussed above, the wafer is cut to separate the individual die 208. At this stage, the distance between the dies 208 is the width of the cut lines between the dies.

As an alternative method and apparatus to expand the gaps 250 between the dies 208 to a distance suitable for placement of the dies on a substrate, a downward force 308 is applied to a pusher pad 312 to thereby exert downward force on the mounting film 216. This downward force (upward or other direction depending on the orientation of the dies 208 and film 216) expands or stretches the mounting film, which in turn expands the dies' locations radially outwards to expand the gap 250 between the dies 208. In this embodiment, the mounting tape 216, once expanded, stays in the expanded position thereby maintaining the gaps 250 even when the pusher pad 312 is removed. In one embodiment, the surface of the pusher pad 312 which contacts the mounting film 216, i.e., the interface between pusher pad and the mounting film, has a low coefficient of friction thereby allowing slippage between the surfaces. In addition, it is contemplated that the pusher pad 312 may be flexible and/or expandable to also flex or expand outward commensurate with the stretched mounting film 216.

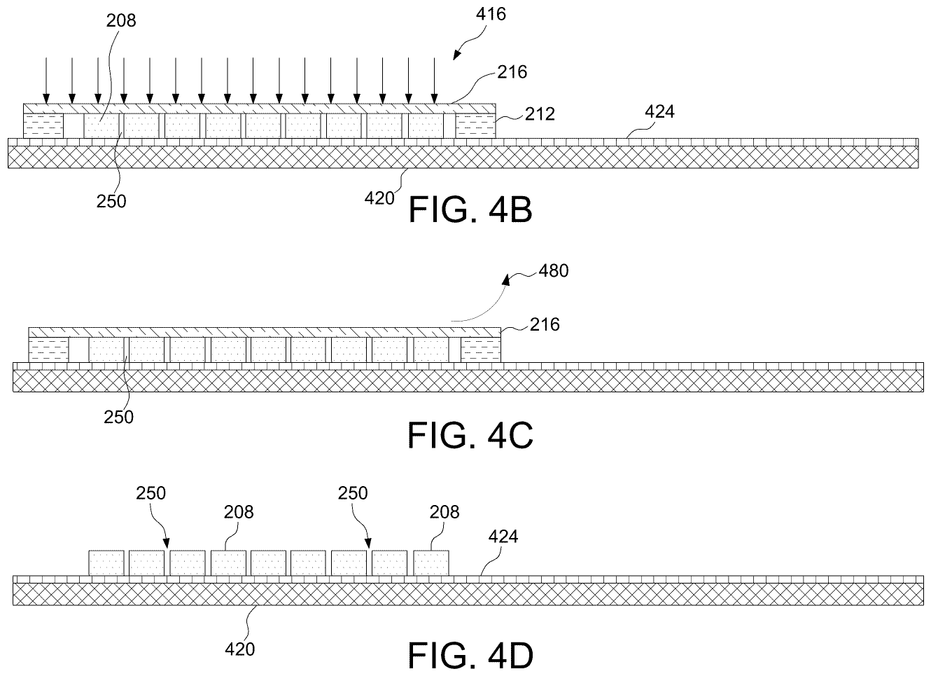

FIG. 4A, FIG. 4B, FIG. 4C, and FIG. 4D illustrate the dies and mounting tape as processed during a large-scale die transfer process onto a substrate or other surface. This is but one possible representation of the processing steps, and there may be additional intermediate steps that would be understood. As shown in FIG. 4A, the structure of FIG. 2B or FIG. 3 is shown but has been flipped upside down in relation to FIG. 2B, such that the mounting film 216 is above dies 208 which are separated by the gaps 250. The wafer and mounting film are stretched to thereby establish the gaps 250 between dies.

The frame 212 is also shown as supporting the mounting film. The frame 212 may or may not be present. The frame 212 may aid in maintaining the desired gap distance between each die, top to bottom and side to side, or in any direction.

FIG. 4B illustrates a carrier substrate 420 and carrier body 424 in addition to the frame 216, dies 208, and mounting tape 216. The carrier body 424 comprises tape or circuits with protective material on the circuits. The carrier substrate 420 may comprise, but is not limited to, metal plates, BT Resin, PI Tape or any similar configuration. It is contemplated that in this embodiment, the carrier substrates 424 may have an adhesive top layer which contacts the dies 208. One surface of the die 208 may have electrical contact or connection points thereon, such as but not limited to bump pads, electrical contact pad, or both.

In the processing step shown in FIG. 4B, the frame 216, die 208, and mounting tape 216 are moved downward onto the top surface of the carrier body 424. As would be understood, the substrate 424 could also be moved upward toward the dies 208. This causes the downwardly facing, exposed surface of the die to contact and become adhesively, electrically, and/or mechanically attached to the body 424 and in turn the substrate 420. As can be seen in FIG. 4B, numerous dies 208 are attached during a single operation, instead of the slower single die at a time transfer process.

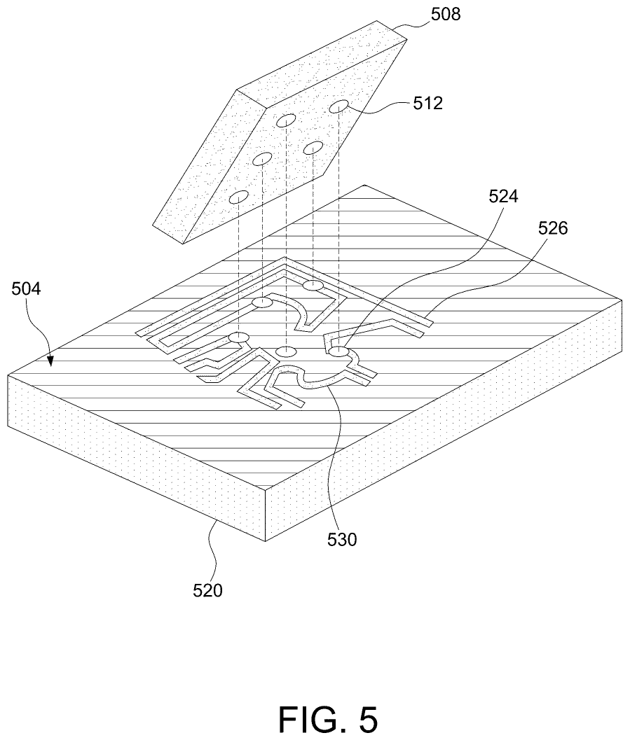

To aid in understanding of the die to substrate connection, FIG. 5 illustrates one exemplary embodiment of a single die to substrate electrical connection. This is but one possible connection structure and using the innovation disclosed herein, many dies can be placed at a time. As shown, a substrate 520 is provided which has a top surface 504 that includes one or more bonding pads 524 and conductive traces 526 connected to at least one of the bond pads 524.

Also shown in FIG. 5 is a die 508 with associated integrated circuits therein. On one or more sides of the die 508 are electrical contacts 512, which may be referred to as chip bumps or solder bumps. These bumps 512 are precisely aligned with the bonding pads 524 on the substrate 520, thereby electrically connecting the die 508 to the substrate when properly aligned. The die 508 is shown at an angle in relation to the substrate 520 to allow a view of the electrical contacts. When placed on the substrates, the die 508 may be parallel to the substrate and moved downward in a direction perpendicular to the substrate.

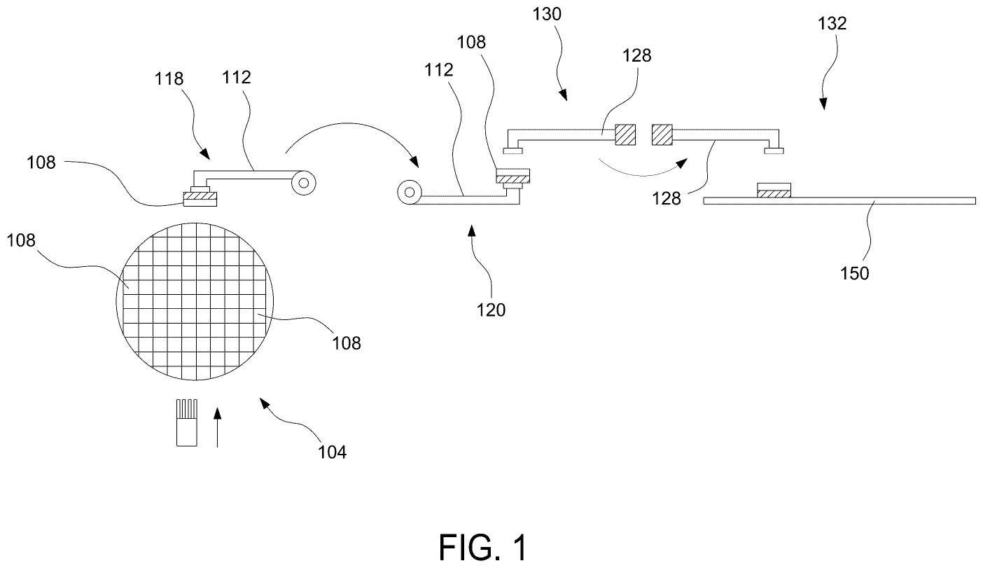

As can be appreciated from the discussion of FIG. 1, individually picking up, aligning, and placing the die is undesirably time consuming. The processing step shown in FIG. 4B overcomes the drawbacks of the prior art by placing an entire wafer of cut dies 208 (or a subset thereof) onto the substrate at one time by applying a downward movement or force 416 to push the expanded dies onto the top surface of the substrate or body. This places the bumps 512 of the die 508 in electrical contact with the bond pads 526 of the substrate 420.

In an alternative embodiment, the carrier 420 may be non-functional in that it does not have electrical contact thereon. As such the carrier 420 may be a metal plate with an adhesive tape (424) to adhesively attach the dies. The adhesive tape may be the same as or similar to the mounting tape 216. In this embodiment, there is no electrically conductive connection between the die 208 and the carrier 420. With the entire wafer of dies 208 adhesively attached to the carrier 420, the dies (attached to the carrier) may be easily and securely moved for further processing. This structure also avoids time consuming single die at a time processing of the prior art.

As shown in FIG. 4C, the mounting film 216 is peeled away from the die 208 using an upward pulling force 480 after the dies are placed on the body/substrate. Due to the adhesive attachment of the dies to the surface 424, the dies are not pulled away from the substrate/carrier when the mounting film is removed. In one embodiment, heat, irradiation with UV or other wavelength light, laser treatments, radiation, or any other process may be applied to the mounting tape 216 to facilitate the mounting tape being removed from the dies 208. The application of some type of energy or substance is selected to weaken the adhesive bond between the mounting tape 216 and the dies 208. As shown in FIG. 4C by force arrow 480, the mounting tape is removed from the die 208.

FIG. 4D shows an entire wafer of die 208 (or portion of the die from the wafer) attached to a substrate or carrier 420 with the mounting tape (not shown in FIG. 4D) removed. The attachment between the dies and the substrates/body 420 may be an adhesive attachment, an electrical connection or both. The multiple dies (up to an entire wafer of dies) are thus placed and electrically connected to a substrate or secured to carrier for further processing. The resulting structure can then be further sawed and separated as is understood in the art. This process saves time as compared to the prior art by placing an entire wafer of dies onto a substrate or carrier at the same time.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A system for placing multiple semiconductor die during a single placement operation comprising:
stretchable mounting tape having a first side and a second side, the first side having an adhesive thereon, the adhesive configured to releasably adhere to two or more semiconductor die;
a frame having an open center portion and a first frame portion and second frame portion forming an outer perimeter wherein the first frame portion and the second frame portion may comprise one or more elements, the frame comprising:
a first frame portion and a second frame portion separated by a first gap and an opposing second gap, the first frame portion and the second frame portion both having a first frame side and a second frame side such that the first frame side is configured to adhesively adhere to the adhesive on the mounting tape;
one or more connections points on the first frame portion, the second frame portion or both, the one or more connection points configured to releasably attach the frame to a frame position control device which determines a length of the first gap and the second gap, which separate the first frame portion and the second frame portion.

2. The system of claim 1 wherein the first frame portion comprises a first section and a second section which are separated by third gap and the second frame portion comprises a third section and a fourth section which are separated by a fourth gap.

3. The system of claim 2 such that the first section and a second section have one or more connection points configured to releasably attach to the frame position control device, and third section and the second section have one or more connection points configured to releasably attach to the frame position control device.

4. The system of claim 1 wherein the open center portion is circular.

5. The system of claim 1 further comprising a pusher configured to push on the mounting tape to increase a distance between the two or more die.

6. The system of claim 1 wherein the frame and the mounting tape can be expanded by applying force along a first axis, a second axis, or both to expand the length of the gaps.

7. The system of claim 1 wherein the two or more dies comprise an entire wafer of die and once expanded, a distance between the two or more dies is increased, thereby allowing the entire wafer of dies to be placed during a single placement operation.

8. A method for placing multiple semiconductor die during a single placement operation comprising:
providing a mounting film having adhesive on at least one side and an expandable frame;
adhesively attaching the mounting film to the expandable frame when the expandable frame in an unexpanded position;
attaching two or more connected semiconductor die to the adhesive on the mounting film;
cutting the two or more semiconductor die to detach the two or more die from each other to create two or more cut die;
attaching the expandable frame to a frame expansion device;
with the frame expansion device, expanding the expandable frame from the unexpanded position to an expanded position, which increases a distance between the two or more cut die to create two or more cut expanded die; and
during a single placement operation, attaching, to a substrate, the two or more cut expanded die on the mounting film.

9. The method of claim 8 further comprising locking the frame in place with one or more frame locks to maintain the frame and the two or more cut expanded die in the expanded position.

10. The method of claim 8 wherein the attaching the two or more die to the substrate comprises an electrical connection between the two or more die and the substrate.

11. The method of claim 8 further comprising applying energy in the form of heat, irradiation, or light energy to the mounting film, and then removing the mounting film from the two or more die, such that the applying energy reduces the adhesive adhesion of the mounting film to the two or more die.

12. The method of claim 8 wherein expanding the expandable frame from the unexpanded position to the expanded position comprises pushing on the mounting film with a pusher pad.

13. The method of claim 8 wherein the expanding the expandable frame comprises expanding the expandable frame and the two or more dies attached to the mounting film along a first axis and along a second axis, where the first axis is perpendicular to and in the same plane as the second axis.

14. The method of claim 8 wherein a side of the two or more die that is not attached to the mounting film is attached to the substrate.

15. A system for holding and placing multiple semiconductor die during a single placement operation comprising:
stretchable mounting film having a first side and a second side, the first side having an adhesive thereon, the adhesive configured to releasably adhere to two or more semiconductor die;
a frame having an open center formed by outer support rails, the outer support rails divided into two or more sections each having a first side and a second side one of which is configured to attach to the mounting film, the two or more sections are expandable from an unexpanded position to an expanded position;
a frame lock configured to interact with a frame lock interface on the frame to secure the frame in the expanded position, the unexpanded position, or both.

16. The system of claim 15 wherein the two or more sections comprise four sections and the frame is expandable along two axis, and an amount of expansion along different access may be different.

17. The system of claim 15 wherein the two or more sections have one or more connection points configured to releasably attach the frame to a position control device, wherein the position control device expands the two or more sections from the unexpanded position to the expanded position.

18. The system of claim 15 wherein the open center is circular having a diameter of 100 mm to 450 mm to accept an entire wafer of dies on the mounting film.

19. The system of claim 15 further comprising a pusher configured to expand the two or more sections from the unexpanded position to the expanded position, and the mounting film attached to the frame.

20. The system of claim 15 wherein the frame includes one or more clamps to attach to the mounting film.

21. The system of claim 15 wherein the two or more dies comprise an entire wafer of cut dies and the frame, mounting film, and the entire wafer of cut dies are configured for movement and processing as a single element, including placement of an entire wafer of cut dies thereby allowing the entire wafer of cut dies to be placed during a single placement operation.
